(19) United States
(12) Patent Application Publication
(10) Pub. No.: US 2006/0188746 A1
(43) Pub. Date: Aug. 24, 2006

(54) Organic Electroluminescent devices and display utilizing the same

(75) Inventor: Chung-Yeh Iou, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/285,563

(22) Filed: Nov. 21, 2005

(30) Foreign Application Priority Data
Feb. 23, 2005 (TW) 94105399

(51) Int. Cl. H01L 51/54; H01L 51/52; H05B 33/14

(52) U.S. Cl. 428/690; 428/917; 428/212; 313/504; 313/506; 257/101; 257/E51.018

(57) ABSTRACT

An organic electroluminescent device (OELD) comprises a substrate, an first electrode, a second electrode opposite to the first electrode disposed over the substrate, a hole-transport layer disposed between the first electrode and the second electrode, an electron-transport layer disposed between the second electrode and the hole-transport layer, and an emissive layer disposed between the hole-transport layer and the electron-transport layer. The emissive layer comprises a plurality of sub-layers. One or more dopants dispersed gradually in the plurality of sub-layers having the substantially identical host material.

### BACKGROUND

The present invention relates generally to an organic electroluminescent device and, more particularly, to an emissive layer having one or more dopants dispersed therein with a concentration gradient.

Current density, luminance efficiency, and chromaticity of CIE coordinates for an organic electroluminescent device (OELD) have been significantly improved.

However, operational lifetime of an OELD, especially a blue OELD, has yet to be improved. Typically, a blue OELD has a half-life of about 1500 hours at a luminance of 1000 nits. Such a device require enhancement when applied in a display panel.

A typical OELD comprises an anode of indium tin oxide (ITO), a hole-injection layer (HIL), a hole-transport layer (HTL), an emissive layer doped with dopants having uniform concentration, an electron-transport layer (ETL), an electron-injection layer (EIL), and a cathode.

When electrical potential difference is applied between the anode and the cathode, electrons and holes are injected into the emissive layer from the cathode and the anode, respectively. The injected electrons and holes are then recombined to produce excitons. Excitons excite the dopants, thereby releasing energy as light.

However, distribution of excitons is confined to a certain region due to difference between hole mobility and electron mobility.

In other words, excitons only exit a certain region of the emissive layer. Thus, dopants may remain in some regions where no excitons exist. Moreover, excitons may not be completely exhausted due to insufficient dopant, producing radiation and heat, thereby significantly reducing operational lifetime of the device.

Accordingly, an OELD capable of solving problems such as shortened operational lifetime due to remaining dopants and excitons is required.

### SUMMARY

The first aspect of the present invention is to enhance current density of driving current, luminance, and stability of an OELD.

The second aspect of the present invention is to completely exhaust excitons formed by recombination of electrons and holes.

To achieve the described aspect, one or more dopants are gradually doped into the emissive layer with a concentration gradient, depending on location. Therefore, the one or more dopants and excitons are completely exhausted, enhancing luminescent efficiency and stability.

According to the present invention, an OELD comprises a substrate, an first electrode, a second electrode opposite to the first electrode disposed over the substrate, a hole-transport layer disposed between the first electrode and the second electrode, an electron-transport layer disposed between the second electrode and the hole-transport layer, and an emissive layer disposed between the hole-transport layer and the electron-transport layer. Moreover, the emissive layer comprises a plurality of sub-layers having the substantially identical host materials, and each of the sub-layers is being doped with a substantially different concentration of one or more dopants.

The OELD of the present invention further comprises a hole-injection layer disposed between the first electrode and the hole-transport layer, and an electron-injection layer disposed between the second electrode and the electron-transport layer.

According to the present invention, the emissive layer is doped in several ways as follows:

First, as shown in FIG. 1, the one or more dopants concentration gradient decreases gradually along the increased thickness direction of the emissive layer.

Second, as shown in FIG. 2, the one or more dopants concentration gradient initially increases gradually along the increased thickness direction of the emissive layer, and then decreases. In other embodiments, the one or more dopants concentration gradient initially decreases gradually along the increased thickness direction of the emissive layer, and then increases.

Third, as shown in FIG. 3, the one or more dopants concentration gradient increases gradually along the thickness of increased direction of the emissive layer.

The concentration of the one or more dopants ranges from about 0.1 vol % to about 99 vol %. The thickness of the emissive layer ranges from about 50 Å to about 2000 Å. The thickness of the hole-injection layer ranges from about 50 Åto about 5000 Å. The thickness of the hole-transport layer ranges from about 50 Å to about 5000 Å. The thickness of the electron-transport layer ranges from about 50 Å to about 5000 Å. The thickness of the electron-injection layer ranges from about 1 Å to about 50 Å. The thickness of the second electrode ranges from about 500 Å to about 5000 Å.

The hole-transport layer comprises one or more diamine derivatives, for example, N,N′-diphenyl-N,N′-bis(1-naphthyl)-(1,1′-bisphenyl)-4,4′-diamine (NPB), N,N1-diphenyl-N,N′-bis(3-methylphenyl)-(1,1′-bisphenyl)-4,4′-diamine (TPD), 4,4′,4″-tris(N-(1-naphtyl)-N-phenyl-amino)-trisphenyl-amine (1T-NATA), or 4,4′,4″-tris(N-(2-naphtyl)-N-phenyl-amino)-trisphenyl-amine (2T-NATA).

The electron-transport layer comprises one or more metal quinolinate derivatives. The electron-injection layer comprises a metal fluoride, an alkali metal derivative, an alkaline metal derivative, or an alkaline-earth metal derivative. In other embodiments, the metal fluoride comprises lithium fluoride (LiF), cesium fluoride (CsF), or sodium fluoride (NaF).

The one or more dopants comprise singlets or triplets, for example, 10-(2-benzothiazolyl)-1,1,7,7-tetramethyl-2,3,6,7-tetrahydro-1H,5H,11H(1)benzopyrano(6,7,8-ij) quinolizin-11-one (C545T), 2-(1,1-dimethylethyl)-6(2-(2,3,6,7-tetrahydro-1,1,7,7-tetramethyl-1H,5H-benzo(ij) quinolizin-9-yl)ethyl)-4H-pyran-4-ylidene)propanedinitrile (DCJTB), or 2,5,8,11-tetrakis(1,1-dimethylethyl)perylene (TBP). In other embodiments, green dopants such as (3-(2′-benzothiazolyl)-7-diethylaminocoumarin(coumarin-6)), or the one or more dopants comprise singlets or triplets capable of emitting three primary colors. In other embodiments, the one or more dopants may be dye.

Moreover, a display utilizing the OELD of the present invention is provided.

### DESCRIPTION OF THE DRAWINGS

The present invention will become more fully understood from the detailed description given herein below and the accompanying drawings, given by way of illustration only and thus not intended to be limitative of the present invention.

FIG. 1 shows distribution of dopants in the emissive layer of an OELD according to the present invention.

FIG. 2 shows distribution of dopants in the emissive layer of an OELD according to the present invention.

FIG. 3 shows distribution of dopants in the emissive layer of an OELD according to the present invention.

FIG. 4 is a graph of the relative luminance as a function of operating time for OELDs of several embodiments and a comparative example.

FIG. 5 is a cross-section of an embodiment of an OELD of the present invention.

FIG. 6 is a cross-section of another embodiment of an OELD of the present invention.

FIG. 7 is a cross-section of another embodiment of an OELD of the present invention.

FIG. 8 is a cross-section of a display apparatus comprising the OELD of the present invention.

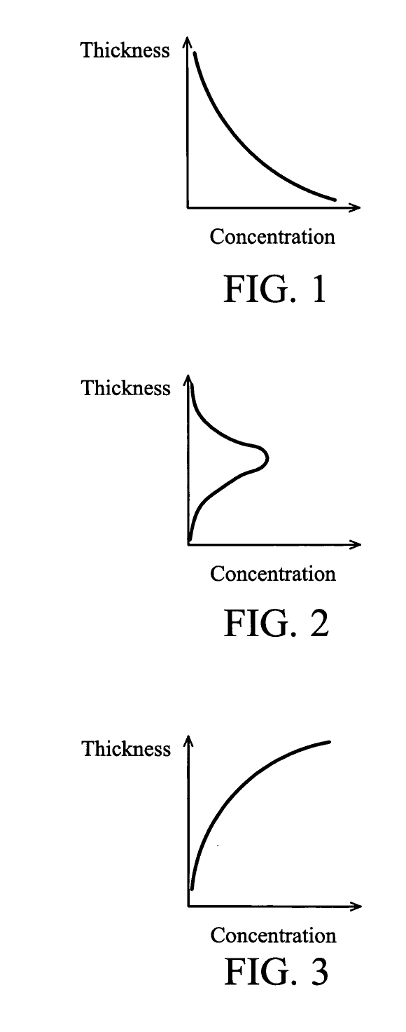

### DETAILED DESCRIPTION

### Comparative example

“Concentration”, herein below described, is defined as a ratio of volume of the dopants and the emission layer.

A conventional OELD and a method for forming are described in greater detail in the following.

A conventional OELD comprises an anode, a thickness of a hole-injection layer (HIL) about 150 nm, a thickness of a hole-transport layer (HTL) about 20 nm, a thickness of a emissive layer about 40 nm, a thickness of a electron-transport layer (ETL) about 20 nm, an electron-injection layer (EIL), and a cathode. Moreover, the emissive layer, having a blue host material, is doped with blue dopants having a concentration of 2.5 vol %.

UV-ozone treatment is performed on a substrate having an anode thereon. The anode is indium tin oxide (ITO).

The 150 nm hole-injection layer is formed on the processed substrate by vacuum deposition.

The hole-transport layer is formed on the hole-injection layer by vacuum deposition.

The emissive layer is formed on the hole-transport layer by vacuum deposition.

The electron-transport layer and an electron-injection layer are formed on the emissive layer by vacuum deposition.

The cathode is formed on the electron-injection layer by vacuum deposition. The cathode comprises a layer of LiF about 1 nm and a layer of Al about 100 nm.

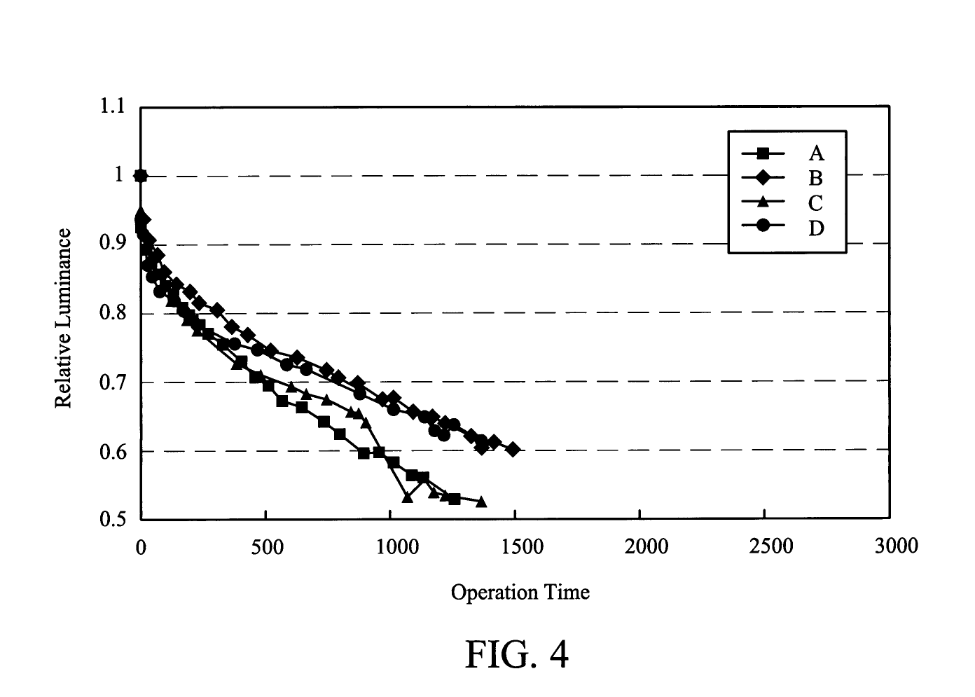

FIG. 4 is a graph of relative luminance as a function of operating time for OELD of a comparative example (see curve-A). The relative luminance is defined as a ratio of initial luminance to luminance. At the same point in operating time, the increased value of relative luminance indicates luminance of the device decaying fast. FIG. 4 illustrates measurement of operating time for a device at initial luminance of 1000 nits.

As shown in Table 1, column 2 shows current density, driving voltage, luminance, luminance efficiency, and CIE coordinates for a device of a comparative example.

TABLE 1

| | comparative | First | Second | Third |
|---|---|---|---|---|
| | example | Embodiment | Embodiment | Embodiment |
| | (A) | (B) | (C) | (D) |
| current | 31.2 | 21.3 | 21.55 | 40.85 |
| density | | | | |
| (mA/cm²) | | | | |
| driving | 7 | 7 | 7 | 7 |
| voltage (V) | | | | |
| luminance | 1392 | 893.5 | 1029 | 1906 |
| (cd/m²) | | | | |
| luminance | 4.47 | 4.2 | 4.77 | 4.67 |
| efficiency | | | | |
| (cd/A) | | | | |
| CIEx | 0.146 | 0.162 | 0.146 | 0.145 |
| CIEy | 0.185 | 0.21 | 0.205 | 0.188 |

### First Embodiment

A top emissive type OELD and method for fabricating are provided. In other embodiments, the OELD may be bottom emissive type, or dual emissive type.

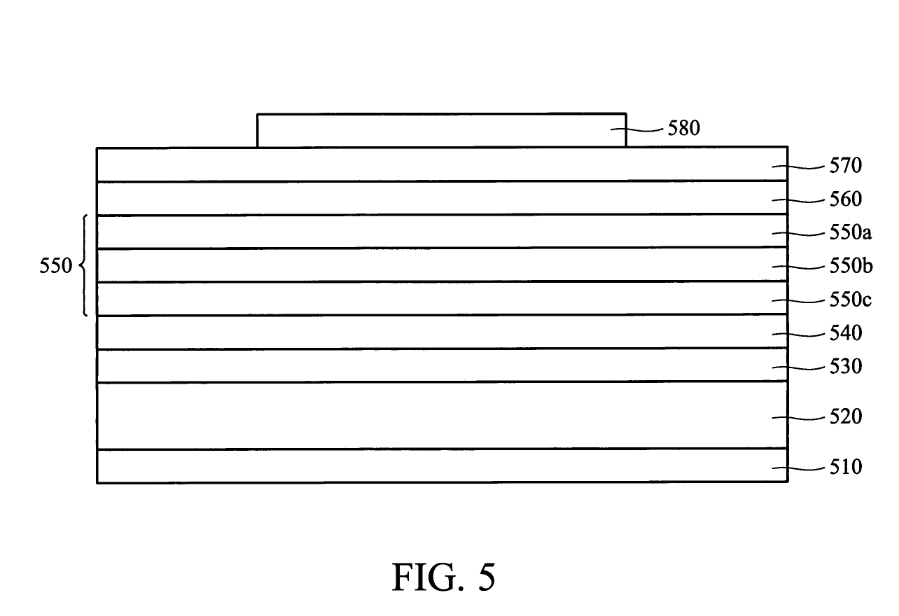

As shown in FIG. 5, the OELD comprises a first electrode such as an anode, the thickness of the hole-injection layer (HIL) substantially about 150 nm, the thickness of the hole-transport layer (HTL) substantially about 20 nm, the thickness of the emissive layer substantially about 40 nm, the thickness of the electron-transport layer (ETL) substantially about 20 nm, the thickness of the electron-injection layer (EIL) substantially about 1 nm, and a second electrode such as a cathode.

UV-ozone treatment is performed on a substrate 510 having an anode formed thereon. The anode 520 is indium tin oxide (ITO). In other embodiments, the anode 520 can be indium zinc oxide (IZO), cadmium tin oxide (CTO), or the like.

The thickness of the hole-injection layer 530 ranges from about 50 Å to about 5000 Å, preferably 150 nm, is formed on the processed substrate 510 by vacuum deposition.

The thickness of the hole-transport layer 540 ranges from about 50 Å to about 5000 Å, preferably 20 nm, is formed on the hole-injection layer 530 by vacuum deposition. The hole-transport layer 540 comprise one or more diamine derivatives such as N,N′-diphenyl-N,N′-bis(1-naphthyl)-(1,1′-bisphenyl)-4,4′-diamine (NPB), N,N′-diphenyl-N,N′-bis(3-methylphenyl)-(1,1′-bisphenyl)-4,4′-diamine (TPD), 4,4′,4″-tris(N-(1-naphtyl)-N-phenyl-amino)-trisphenyl-amine (1T-NATA) or 4,4′,4″-tris(N-(2-naphtyl)-N-phenyl-amino)-trisphenyl-amine (2T-NATA).

The thickness of the emissive layer 550 ranges from about 50 Å to about 2000 Å, preferably 40 nm, is formed on the hole-transport layer 540 by vacuum deposition.

The electron-transport layer 560 ranges from about 50 Åto about 5000 Å and The electron-injection layer 570 ranges from about 1 Å to about 50 Å are formed on the emissive layer 550 by vacuum deposition. The electron-transport layer 560 comprises Tris-(8-hydroxyquinolinate) aluminum (III) (Alq3), Tris-(8-hydroxyquinolinate)gallium(III) (Gaq3), or Tris-(8-hydroxyquinolinate) Indium (III) (Inq3). The electron-injection layer 570 comprises a metal fluoride, an alkali metal derivative, an alkaline metal derivative, or an alkaline-earth metal derivative. Moreover, the metal fluoride comprises LiF, CsF, or NaF.

The thickness of the cathode 580 ranges from about 500 Å to about 5000 Å is formed on the electron-injection layer 570 by vacuum deposition. The cathode 580 comprises a layer of LiF substantially about 1 nm and a layer of Al substantially about 100 nm.

Moreover, the emissive layer 550, having blue host materials, comprises sub-layers 550a, 550b, and 550c. The thickness of the sub-layer 550a can be substantially about 100 nm, and is doped with the concentration of the one or more blue dopants can be substantially about 8 vol %. The thickness of the sub-layer 550b can be substantially about 100 nm, doped with the concentration of the one or more blue dopants can be substantially about 5 vol %. The thickness of the sub-layer 550c can be substantially about 100 nm, and is doped with the concentration of the one or more blue dopants can be substantially about 2.5 vol %. The one or more dopants comprise 10-(2-benzothiazolyl)-1,1,7,7-tetramethyl-2,3,6,7-tetrahydro-1H,5H,11H(1)benzopyrano(6,7,8-ij) quinolizin-11-one (C545T), 2-(1,1-dimethylethyl)-6(2-(2,3,6,7-tetrahydro-1,1,7,7-tetramethyl-1H,5H-benzo(ij) quinolizin-9-yl)ethyl)-4H-pyran-4-ylidene)propanedinitrile (DCJTB), or 2,5,8,11-tetrakis(1,1-dimethylethyl)perylene (TBP). In other embodiments, the one or more dopants comprise one or more green dopants such as 3-(2′-benzothiazolyl)-7-diethylaminocoumarin(coumarin-6). In other embodiments, the one or more dopants comprise singlets or triplets capable of emitting three primary colors. In other embodiments, the one or more dopants may be dye.

FIG. 4 is a graph of the relative luminance as a function of operating time for OELD of a first embodiment (see curve-B).

As shown in Table 1, column 3 shows current density, driving voltage, luminance, luminance efficiency, and CIE coordinates for the device of first embodiment.

### Second Embodiment

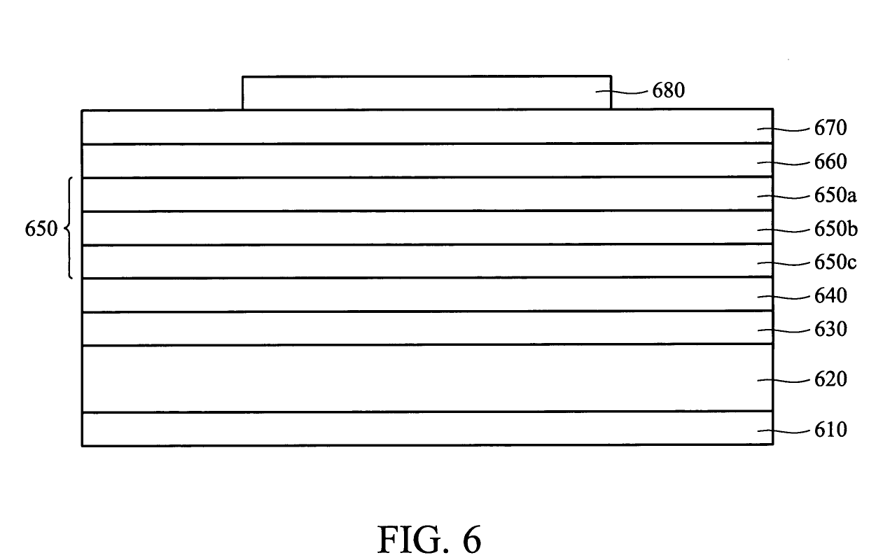

As shown in FIG. 6, an OELD comprises a first electrode such as an anode, the thickness of the hole-injection layer (HIL) substantially about 150 nm, the thickness of the hole-transport layer (HTL) substantially about 20 nm, the thickness of the emissive layer substantially about 40 nm, the thickness of the electron-transport layer (ETL) substantially about 20 nm, the thickness of the electron-injection layer (EIL) substantially about 1 nm, and a second electrode such as a cathode.

UV-ozone treatment is performed on a substrate 610 having an anode formed thereon. The anode 620 is indium tin oxide (ITO). In other embodiments, the anode 620 can be indium zinc oxide (IZO), cadmium tin oxide (CTO), or the like.

The thickness of the hole-injection layer 630 ranges from about 50 Å to about 5000 Å, preferably 150 nm, is formed on the processed substrate 610 by vacuum deposition.

The thickness of the hole-transport layer 640 ranges from about 50 Å to about 5000 Å, preferably 20 nm, is formed on the hole-injection layer 630 by vacuum deposition. The hole-transport layer 640 comprise one or more diamine derivatives such as N,N′-diphenyl-N,N′-bis(1-naphthyl)-(1,1′-bisphenyl)-4,4′-diamine (NPB), N,N′-diphenyl-N,N1-bis(3-methylphenyl)-(1,1′-bisphenyl)-4,4′-diamine (TPD), 4,4′,4″-tris(N-(1-naphtyl)-N-phenyl-amino)-trisphenyl-amine (1T-NATA) or 4,4′,4″-tris(N-(2-naphtyl)-N-phenyl-amino)-trisphenyl-amine (2T-NATA).

The thickness of the emissive layer 650 ranges from about 50 Å to about 2000 Å, preferably 40 nm, is formed on the hole-transport layer 640 by vacuum deposition.

The thickness of the electron-transport layer 660 ranges from about 50 Å to about 5000 Å and The thickness of the electron-injection layer 670 ranges from about 1 Å to about 50 Å are formed on the emissive layer 650 by vacuum deposition. The electron-transport layer 660 comprises Tris-(8-hydroxyquinolinate) aluminum (III) (Alq3), Tris-(8-hydroxyquinolinate)gallium(III) (Gaq3), or Tris-(8-hydroxyquinolinate) Indium (III) (Inq3). The electron-injection layer 670 comprises a metal fluoride, an alkali metal derivative, alkaline metal derivative, or an alkaline-earth metal derivative. Moreover, the metal fluoride comprises LiF, CsF, or NaF.

The thickness of the cathode 680 ranges from about 500 Å to about 5000 Å is formed on the electron-injection layer 670 by vacuum deposition. The cathode 680 comprises a layer of LiF substantially about 1 nm and a layer of Al substantially about 100 nm.

Moreover, the emissive layer 650, having blue host materials, comprises sub-layers 650a, 650b, 650c and 650d. The thickness of the sub-layer 650a can be substantially about 100 nm, and is doped with the concentration of the one or more blue dopants can be substantially about 10 vol %. The thickness of the sub-layer 650b can be substantially about 100 nm, doped with the concentration of the blue one or more dopants can be substantially about 7.5 vol %. The thickness of the sub-layer 650c can be substantially about 100 nm, and is doped with the concentration of the one or more blue dopants can be substantially about 5 vol %. The thickness of the sub-layer 650d can be substantially about 100 nm, and is doped with the one or more blue dopants at a concentration of 2.5 vol %. The one or more dopants comprise 10-(2-benzothiazolyl)-1,1,7,7-tetramethyl-2,3,6,7-tetrahydro-1H,5H,11H(1)benzopyrano(6,7,8-ij) quinolizin-11-one (C545T), 2-(1,1-dimethylethyl)-6(2-(2,3,6,7-tetrahydro-1,1,7,7-tetramethyl-1H,5H-benzo(ij) quinolizin-9-yl)ethyl)-4H-pyran-4-ylidene)propanedinitrile (DCJTB), or 2,5,8,11-tetrakis(1,1-dimethylethyl)perylene (TBP). In other embodiments, the one or more dopants can comprise green dopants such as 3-(2′-benzothiazolyl)-7-diethylaminocoumarin(coumarin-6), or singlets or triplets capable of emitting three primary colors. In other embodiments, the one or more dopants may be dye.

FIG. 4 is a graph of the relative luminance as a function of operating time for the OELD of a second embodiment (see curve-C).

As shown in Table 1, column 4 shows current density, driving voltage, luminance, luminance efficiency, and CIE coordinates for the device of second embodiment.

### Third Embodiment

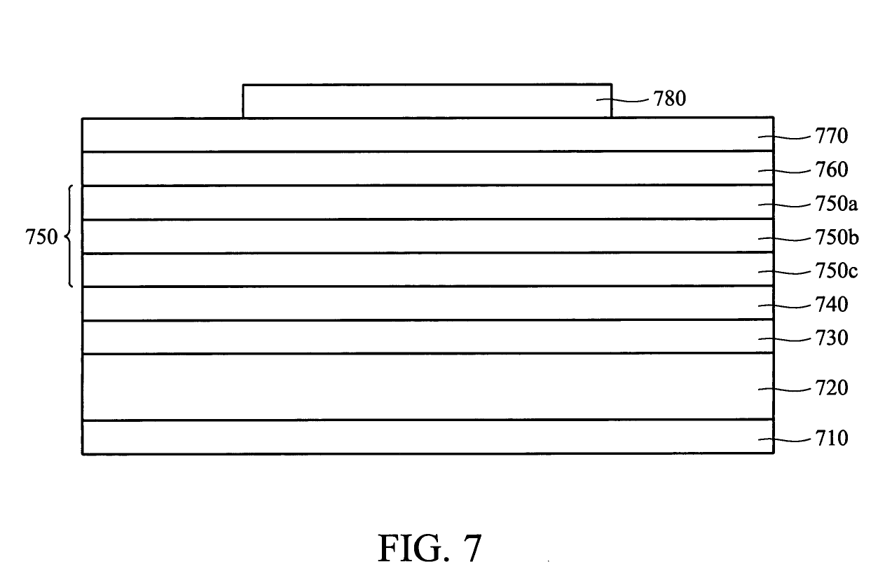

As shown in FIG. 7, the OELD comprises a first electrode such as an anode, the thickness of the hole-injection layer (HIL) substantially about 150 nm, the thickness of the hole-transport layer (HTL) substantially about 20 nm, the thickness of the emissive layer substantially about 40 nm, the thickness of the electron-transport layer (ETL) substantially about 20 nm, the thickness of the electron-injection layer (EIL) substantially about 1 nm, and a second electrode such as a cathode.

UV-ozone treatment is performed on a substrate 710 having the anode formed thereon. The anode 720 is indium tin oxide (ITO). In other embodiments, the anode 720 can be indium zinc oxide (IZO), cadmium tin oxide (CTO), or the like.

The thickness of the hole-injection layer 730 ranges from about 50 Å to about 5000 Å, preferably 150 nm, is formed on the processed substrate 710 by vacuum deposition.

The thickness of the hole-transport layer 740 ranges from about 50 Å to about 5000 Å, preferably 20 nm, is formed on the hole-injection layer 730 by vacuum deposition. The hole-transport layer 740 comprise one or more diamine derivatives such as N,N1-diphenyl-N,N1-bis(1-naphthyl)-(1,1′-bisphenyl)-4,4′-diamine (NPB), N,N′-diphenyl-N,N′-bis(3-methylphenyl)-(1,1′-bisphenyl)-4,4′-diamine (TPD), 4,4′,4″-tris(N-(1-naphtyl)-N-phenyl-amino)-trisphenyl-amine (1T-NATA) or 4,4′,4″-tris(N-(2-naphtyl)-N-phenyl-amino)-trisphenyl-amine (2T-NATA).

The thickness of the emissive layer 750 ranges from about 50 Å to about 2000 Å, preferably 40 nm, is formed on the hole-transport layer 740 by vacuum deposition.

The thickness of the electron-transport layer 760 ranges from about 50 Å to about 5000 Å and The thickness of the electron-injection layer 770 ranges from about 1 Å to about 50 Å are formed on the emission layer 750 by vacuum deposition. The electron-transport layer 760 comprises Tris-(8-hydroxyquinolinate) aluminum (III) (Alq3), Tris-(8-hydroxyquinolinate)gallium(III) (Gaq3), or Tris-(8-hydroxyquinolinate) Indium (III) (Inq3). The electron-injection layer 770 comprises a metal fluoride, an alkali metal derivative, an alkaline metal derivative, or an alkaline-earth metal derivative. Moreover, the metal fluoride comprises LiF, CsF, or NaF.

The thickness of the cathode 780 ranges from about 500 Å to about 5000 Å is formed on the electron-injection layer 770 by vacuum deposition. The cathode 780 comprises a layer of LiF substantially about 1 nm and a layer of Al substantially about 100 nm.

The emissive layer 750, having blue host materials, comprises sub-layers 750a, 750b, 750c and 750d. The thickness of the sub-layer 750a can be substantially about 100 nm, and is doped with the concentration of the one or more blue dopants can be substantially about 15 vol %. The thickness of the sub-layer 750b can be substantially about 100 nm, doped with the concentration of the one or more blue dopants can be substantially about 10 vol %. The thickness of the sub-layer 750c can be substantially about 100 nm, and is doped with the concentration of the one or more blue dopants can be substantially about 5 vol %. The thickness of the sub-layer 750d can be substantially about 100 nm, and is doped with the concentration of the one or more blue dopants can be substantially about 2.5 vol %. The one or more dopants comprise 10-(2-benzothiazolyl)-1,1,7,7-tetramethyl-2,3,6,7-tetrahydro-1H,5H,11H(1)benzopyrano(6,7,8-ij) quinolizin-11-one (C545T), 2-(1,1-dimethylethyl)-6(2-(2,3,6,7-tetrahydro-1,1,7,7-tetramethyl-1H,5H-benzo(ij) quinolizin-9-yl)ethyl)-4H-pyran-4-ylidene)propanedinitrile (DCJTB), or 2,5,8,11-tetrakis(1,1-dimethylethyl)perylene (TBP). In other embodiments, the one or more dopants comprise one or more green dopants such as 3-(2′-benzothiazolyl)-7-diethylaminocoumarin(coumarin-6), or singlets or triplets capable of emitting three primary colors. In other embodiments, the one or more dopants may be dye.

FIG. 4 is a graph of relative luminance as a function of operating time for OELD of a third embodiment (see curve-D).

As shown in Table 1, column 5 shows current density, driving voltage, luminance, luminance efficiency, and CIE coordinates for the device of third embodiment.

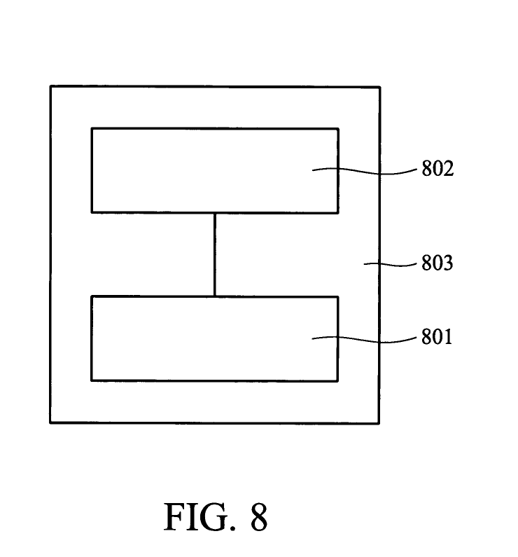

In other embodiments of the present invention, a display 803 comprising the described OELD 802 and a driving circuit 801 can also be provided. The OELD 802 is coupled with the driving circuit 801, as shown in FIG. 8.

While the present invention has been described by way of example and in terms of preferred embodiment, it is to be understood that the present invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An organic electroluminescent device (OELD), comprising:
a substrate;
a first electrode and a second electrode opposite to the first electrode disposed over the substrate;
a hole-transport layer disposed between the first electrode and the second electrode;
an electron-transport layer disposed between the second electrode and the hole-transport layer; and
an emissive layer disposed between the hole-transport layer and the electron-transport layer,
wherein the emissive layer comprising a plurality of sub-layers having a substantially identical host material, and each of the sub-layers being doped with a substantially different concentration of one or more dopants.

2. The OELD of claim 1, further comprising:
a hole-injection layer disposed between the first electrode and the hole-transport layer; and
an electron-injection layer disposed between the second electrode and the electron-transport layer.

3. The OLED of claim 1, wherein the thickness of the emissive layer ranges from about 50 Å to about 2000 Å.

4. The OLED of claim 1, wherein the concentration of the one or more dopants ranges from about 0.1 vol % to about 99 vol %.

5. The OLED of claim 4, wherein the concentration of the one or more dopants within each of the sub-layers decreases along the increased direction of the thickness of the emissive layer.

6. The OLED of claim 4, wherein the concentration of the one or more dopants within each of the sub-layers increases along the increased direction of the thickness of the emissive layer.

7. The OLED of claim 4, wherein the concentration of the one or more dopants within each of the sub-layers initially increases gradually along the increased direction of the thickness of the emissive layer, and then decreases gradually.

8. The OLED of claim 4, wherein the concentration of the one or more dopants within each of the sub-layers initially decreases gradually along the increased direction of the thickness of the emissive layer, and then increases gradually.

9. The OLED of claim 2, wherein the thickness of the hole-injection layer ranges from about 50 Å to about 5000 Å.

10. The device of claim 1, wherein the hole-transport layer comprises one or more diamine derivatives.

11. The OLED of claim 10, wherein the one or more diamine derivatives comprise N,N′-diphenyl-N,N′-bis(1-naphthyl)-(1,1′-bisphenyl)-4,4′-diamine (NPB), N,N1-diphenyl-N,N′-bis(3-methylphenyl)-(1,1′-bisphenyl)-4,4′-diamine (TPD), 4,4′,4″-tris(N-(1-naphtyl)-N-phenyl-amino)trisphenyl-amine (1T-NATA), or 4,4′,4″-tris(N-(2-naphtyl)-N-phenyl-amino)-trisphenyl-amine (2T-NATA).

12. The OLED of claim 1, wherein the thickness of the hole-transport layer ranges from about 50 Å to about 5000 Å.

13. The OLED of claim 1, wherein the electron-transport layer comprises one or more metal chelate derivatives.

14. The OLED of claim 1, wherein the thickness of the electron-transport layer ranges from about 50 Å to about 5000 Å.

15. The OLED of claim 2, wherein the electron-injection layer comprises a metal fluoride, an alkali metal derivative, an alkaline metal derivative, or an alkaline-earth metal derivative.

16. The OLED of claim 15, wherein the metal fluoride comprise LiF, CsF, or NaF.

17. The OLED of claim 2, wherein the thickness of the electron-injection layer ranges from about 1 Å to about 50 Å.

18. The OLED of claim 1, wherein the thickness of the second electrode ranges from about 500 Å about 5000 Å.

19. The OLED of claim 1, wherein the one or more dopants comprise singlets or triplets.

20. The OLED of claim 1, wherein the one or more dopants comprise 10-(2-benzothiazolyl)-1,1,7,7-tetramethyl-2,3,6,7-tetrahydro-1H,5H,11H(1)benzopyrano(6,7,8-ij) quinolizin-11-one (C545T), 2-(1,1-dimethylethyl)-6(2-(2,3,6,7-tetrahydro-1,1,7,7-tetramethyl-1H,5H-benzo(ij) quinolizin-9-yl)ethyl)-4H-pyran-4-ylidene)propanedinitrile (DCJTB), or 2,5,8,11-tetrakis(1,1-dimethylethyl)perylene (TBP).

21. A display comprising an organic electroluminescent device of claim 1.
